(19) United States
(12) Patent Application Publication
(10) Pub. No.: US 2025/0236812 A1
(43) Pub. Date: Jul. 24, 2025

(54) CLEANING AGENT COMPOSITION FOR SEMICONDUCTOR CLEANING, AND METHOD OF CLEANING SEMICONDUCTOR SUBSTRATE

(71) Applicant: Shin-Etsu Chemical Co., Ltd., Tokyo (JP)

(72) Inventors: Koki KASABATA, Gunma (JP); Masahiro YAMAKI, Gunma (JP)

(21) Appl. No.: 19/032,478

(22) Filed: Jan. 21, 2025

(30) Foreign Application Priority Data
Jan. 22, 2024 (JP) 2024-007149

(51) Int. Cl. C11D 1/835; C11D 1/62; C11D 1/72; C11D 3/30; C11D 3/32; C11D 3/43; H01L 21/02

(52) U.S. Cl. CPC C11D 1/835; C11D 3/30; C11D 3/32; C11D 3/43; H01L 21/02068; C11D 1/62; C11D 1/72

(57) ABSTRACT

Provided is a cleaning agent composition for semiconductor cleaning, containing: a quaternary ammonium salt; and an acid amide compound represented by Chemical Formula 1. Here, R₁ to R₃ are organic groups, R₁ contains at least one heteroatom, and Chemical Formula 1 does not include a cyclic structure in which two or more selected from R₁ to R₃ are linked. Provided is a method of cleaning a semiconductor substrate, including applying the cleaning agent composition to a semiconductor substrate in which a silicone-containing temporary adhesive material remains on at least one surface to clean the semiconductor substrate.

The contents of the following patent application(s) are incorporated herein by reference: NO. 2024-007149 filed in JP on Jan. 22, 2024.

### BACKGROUND

### 1. Technical Field

The present invention relates to a cleaning agent composition for semiconductor cleaning and a method of cleaning a semiconductor substrate.

### 2. Related Art

Patent Document 1 discloses “A cleaning agent composition used to remove temporary adhesive containing a silicone compound that is present on a substrate,
the cleaning agent composition comprising:
(A) an organic solvent: 75 to 99 parts by mass;
(B) water: 0 to 5 parts by mass; and
(C) an ammonium salt: 1 to 20 parts by mass
   (where (A)+ (B)+ (C)=100 parts by mass), wherein
the organic solvent does not contain an organic solvent having a hydroxyl group and contains, in 100 parts by mass of the organic solvent, 50 parts by mass or more of an organic solvent having a heteroatom, and
the ammonium salt contains at least one kind of a hydroxide ion, a fluoride ion, and a chloride ion. (claim 1)”.

Patent Document 2 describes that “A composition comprising: a quaternary alkylammonium fluoride or a hydrate of a quaternary alkylammonium fluoride; and an aprotic solvent, wherein the aprotic solvent contains
(A) an N-substituted amide compound having 4 or more carbon atoms and not containing active hydrogen on a nitrogen atom, and
(B) an ether compound. (claim 1)”.

Patent Document 3 describes that “A cleaning agent composition used to remove an adhesive residue, comprising
a quaternary ammonium salt and a solvent containing a first organic solvent and a second organic solvent, wherein
the first organic solvent is an acid amide derivative represented by Formula Z,
the second organic solvent is another organic solvent different from the acid amide derivative, and
a water content is less than 4.0 mass %. (claim 1)”.

### PRIOR ART DOCUMENTS

### Patent Documents

Patent Document 1: WO2020/235605 A
Patent Document 2: WO2020/080060 A
Patent Document 3: WO2021/100651 A

### BRIEF DESCRIPTION OF THE DRAWINGS

FIG. 1 schematically shows an example of a cleaning target object 10 of a cleaning agent composition in the present embodiment.

FIG. 2 shows a flow of a method of manufacturing a semiconductor mounting substrate using the cleaning agent composition of the present embodiment.

FIG. 3 shows a pre-thinning semiconductor substrate 140 joined to a support 130 with a temporary adhesive material 150.

FIG. 4 shows the semiconductor substrate 110 obtained by thinning the pre-thinning semiconductor substrate 140.

FIG. 5 shows an electrode 112 penetrating the semiconductor substrate 110.

FIG. 6 shows an example of a subflow of a cleaning step (S500).

FIG. 7 shows an example of a semiconductor mounting substrate 100.

### DESCRIPTION OF EXEMPLARY EMBODIMENTS

Hereinafter, the invention will be described through embodiments of the invention, but the following embodiments do not limit the invention according to claims. Not all combinations of features described in the embodiments are essential for the solution of the invention. Also, the embodiment(s) will be described with reference to the drawings. The identical or similar parts in the drawings may be given the same reference numerals to omit the description that could otherwise overlap.

### (Overview of Cleaning Target Object 10)

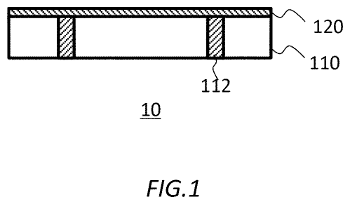

FIG. 1 schematically shows an example of a cleaning target object 10 of a cleaning agent composition in the present embodiment. The cleaning target object 10 is a cleaning target to be cleaned with the cleaning agent composition. The cleaning target object 10 may be various objects in which a silicone-containing adhesive material (hereinafter also referred to as “temporary adhesive material”) adheres to its surface. The adhesive material on the surface is cleaned with the cleaning agent composition.

For example, the cleaning target object 10 may be a semiconductor substrate in which a silicone-containing temporary adhesive material remains on at least one surface. For example, the semiconductor substrate may be reinforced by a support during electrode formation or the like, and the silicone-containing temporary adhesive material used for joining with the support may remain. In the example of FIG. 1, the cleaning target object 10 may include at least a semiconductor substrate 110, an electrode 112, and a temporary adhesive material 120.

The semiconductor substrate 110 may be a semiconductor substrate in which a circuit (not illustrated) is formed on one surface (for example, an upper side in FIG. 1). For example, the semiconductor substrate 110 may be a silicon wafer.

The electrode 112 is an electrode formed on the surface and/or inside of the semiconductor substrate 110. For example, the electrode 112 may be a through electrode (through-silicon via: TSV) provided so as to penetrate the semiconductor substrate 110. The electrode 112 may include an electrode provided on the surface of the semiconductor substrate 110 such as a surface bump.

The temporary adhesive material 120 is an adhesive material remaining on the surface of the semiconductor substrate 110. The temporary adhesive material 120 may remain on the circuit surface side of the semiconductor substrate 110. In a manufacturing process of a semiconductor mounting substrate described later, the temporary adhesive material 120 is provided for joining with a support and remains after delamination of the support. The temporary adhesive material 120 is cleaned and removed by the cleaning agent composition of the present embodiment, thereby completing the semiconductor mounting substrate.

### (Overview of Cleaning Agent Composition)

The cleaning agent composition in the present embodiment will be described. The cleaning agent composition may be mainly used for semiconductor cleaning. In particular, the cleaning agent composition may be used to clean the silicone-containing temporary adhesive material 120 remaining on the semiconductor substrate 110. The cleaning agent composition contains at least (1) a quaternary ammonium salt and (2) an acid amide compound represented by following Chemical Formula 1. The cleaning agent composition may further contain one or both of (3) a non-polar solvent and (4) an ether component.

### ((1) Quaternary Ammonium Salt)

The quaternary ammonium salt may contain only a first ammonium salt (one kind). Alternatively, the quaternary ammonium salt may contain a first ammonium salt and a second ammonium salt (two kinds).

The first ammonium salt is represented by R_{A}R_{B}R_{C}R_{D}N⁺F⁻. Here, R_{A} to R_{D} are each independently selected from an alkyl group, an aryl group, and an aralkyl group.

The alkyl group may be a linear, branched, and/or cyclic group with a carbon number of 1 to 20 (preferably 1 to 10). For example, the alkyl group may be methyl, ethyl, propyl, n-propyl, isopropyl, butyl, n-butyl, isobutyl, tert-butyl, sec-butyl, n-pentyl, isopentyl, neopentyl, tert-pentyl, hexyl, n-hexyl, 1-methylpentyl, 2-methylpentyl, 4-methyl-2-pentyl, 1-methyl-butyl, 1-ethyl-butyl, pentyl, 3,3-dimethylbutyl, 2-ethylbutyl, heptyl, tert-octyl, 1-methylheptyl, 2-ethylhexyl, 2-propylpentyl, n-nonyl, 2,2-dimethylheptyl, 1-ethyl-propyl, 1,1-dimethyl-propyl, isohexyl, 2-methylpentyl, 4-methylhexyl, 5-methylhexyl, or, 2,6-dimethylheptan-4-yl, n-heptyl, 1-methylhexyl, octyl, n-octyl, or the like.

The aryl group may be a monocyclic or polycyclic group with a carbon number of 5 to 30 (preferably 6 to 12). For example, the aryl group may be a phenyl group, a biphenyl group, a terphenyl group, a naphthyl group, an anthracenyl group, a phenanthrenyl group, a pyrenyl group, a perylenyl group, a chrysenyl group, or a fluorenyl group. The aryl group may be unsubstituted or may be substituted with an alkyl group or another functional group.

The aralkyl group may be formed by substituting hydrogen of the above-described alkyl group with the above-described aryl group.

As an example, the first ammonium salt may be a compound in which R_{A} to R_{D} are methyl groups, a compound in which R_{A} to R_{D} are ethyl groups, a compound in which R_{A} to R_{D} are propyl groups, a compound in which R_{A} to R_{D} are isopropyl groups, a compound in which R_{A} to R_{D} are n-butyl groups, a compound in which R_{A} to R_{D} are iso-butyl groups, a compound in which R_{A} to R_{D} are sec-butyl groups, or a compound in which R_{A} to R_{D} are tert-butyl groups.

The first ammonium salt may be a hydrate. Alternatively, the first ammonium salt may be an anhydride.

The cleaning agent composition may contain the first ammonium salt in an amount of 0.1 to 20.0 mass %, preferably 1 to 10 mass %, and more preferably 3 to 6 mass % in the entire cleaning agent composition.

By containing the first ammonium salt contained in the cleaning agent composition, the detergency of the cleaning agent composition can be enhanced. In particular, the first ammonium salt containing a fluorine ion contributes to dissolving/decomposing the silicone-containing temporary adhesive material.

The second ammonium salt is represented by R_{E}R_{F}R_{G}R_{H}N⁺X⁻. Here, R_{E} to R_{H} are each independently selected from an alkyl group, an aryl group, and an aralkyl group. The alkyl group, the aryl group, and the aralkyl group may be the similar to those described in the first ammonium salt. X may be selected from CI, Br, I and OH. Preferably, X may be CI, Br, or I.

The second ammonium salt may be a hydrate. Alternatively, the second ammonium salt may be an anhydride.

The cleaning agent composition may contain the second ammonium salt in an amount of 0.1 to 5.0 mass %, preferably 1 to 4 mass %, in the entire cleaning agent composition.

The second ammonium salt can reduce the polarity of the cleaning agent composition while reinforcing the detergency of the first ammonium salt. As compared with the case of using only the first ammonium salt, when the cleaning agent composition contains the second ammonium salt, the polarity of the cleaning agent composition can be reduced, the cleaning agent composition can easily permeate into the temporary adhesive material containing silicone, and decomposition products can be easily dissolved in the cleaning agent composition.

The quaternary ammonium salt may further contain another ammonium salt in addition to the first ammonium salt and the second ammonium salt.

((2) Acid amide compound represented by Chemical Formula 1)

The acid amide compound is represented by following Chemical Formula 1.

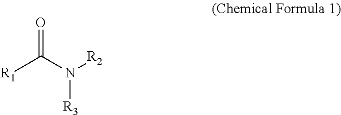

In Chemical Formula 1, R₁ to R₃ are organic groups. Chemical Formula 1 does not include a cyclic structure in which two or more selected from R₁ to R₃ are linked. For example, Chemical Formula 1 does not include a cyclic structure in which R₁ and R₂ are bonded, a cyclic structure in which R₂ and R₃ are bonded, a cyclic structure in which R₁ and R₃ are bonded, and a cyclic structure in which R₁ to R₃ are bonded.

The acid amide compound increases the polarity of the cleaning agent composition. In a case where the cleaning agent composition does not contain the acid amide compound, the polarity is excessively deviated between the quaternary ammonium salt (particularly, first ammonium salt) and other components, and there is a possibility that phase separation occurs or permeation into the temporary adhesive material is delayed. When the cyclic structure in which R₁ to R₃ are linked to each other is formed, there is a possibility that the permeability into the temporary adhesive material decreases, but according to the present embodiment, the permeability into the temporary adhesive material can be enhanced by eliminating such a cyclic structure. Furthermore, by containing the acid amide compound, the decomposition products can be easily dissolved in the cleaning agent composition.

R₁ is an organic group containing at least one heteroatom. For example, the heteroatom may be O, N, or S. As an example, R₁ includes a —R—O—R′ structure, and R and R′ may be alkyl groups. R and R′ may be a linear, branched, and/or cyclic alkyl group with a carbon number of 1 to 20 (preferably 1 to 10). The total carbon number of R and R′ may be 3 or 4 or more. That is, R₁ may have a carbon number of 3 or 4 or more. The acid amide compound can maintain an appropriate polarity by adopting this type of structure.

For example, R and R′ may be each independently selected from methyl, ethyl, propyl, n-propyl, isopropyl, butyl, n-butyl, isobutyl, tert-butyl, sec-butyl, n-pentyl, isopentyl, neopentyl, tert-pentyl, hexyl, n-hexyl, 1-methylpentyl, 2-methylpentyl, 4-methyl-2-pentyl, 1-methyl-butyl, 1-ethyl-butyl, pentyl, 3,3-dimethylbutyl, 2-ethylbutyl, heptyl, tert-octyl, 1-methylheptyl, 2-ethylhexyl, 2-propylpentyl, n-nonyl, 2,2-dimethylheptyl, 1-ethyl-propyl, 1,1-dimethyl-propyl, isohexyl, 2-methylpentyl, 4-methylhexyl, 5-methylhexyl, or, 2,6-dimethylheptan-4-yl, n-heptyl, 1-methylhexyl, octyl, n-octyl, or the like.

R and R′ may have the same structure. Alternatively, R and R′ may have different structures. Note that strictly speaking, R is a divalent alkylene group, but R may have a structure in which hydrogen is removed from the alkyl group described above.

R₂ and R₃ are alkyl groups. R₂ and R₃ may be a linear, branched, and/or cyclic alkyl group with a carbon number of 1 to 20 (preferably 1 to 10). For example, at least one of R₂ or R₃ may have a carbon number of 1 or more, 3 or more, or 5 or more.

R₂ and R₃ may be selected from methyl, ethyl, propyl, n-propyl, isopropyl, butyl, n-butyl, isobutyl, tert-butyl, sec-butyl, n-pentyl, isopentyl, neopentyl, tert-pentyl, hexyl, n-hexyl, 1-methylpentyl, 2-methylpentyl, 4-methyl-2-pentyl, 1-methyl-butyl, 1-ethyl-butyl, pentyl, 3,3-dimethylbutyl, 2-ethylbutyl, heptyl, tert-octyl, 1-methylheptyl, 2-ethylhexyl, 2-propylpentyl, n-nonyl, 2,2-dimethylheptyl, 1-ethyl-propyl, 1,1-dimethyl-propyl, isohexyl, 2-methylpentyl, 4-methylhexyl, 5-methylhexyl, or, 2,6-dimethylheptan-4-yl, n-heptyl, 1-methylhexyl, octyl, n-octyl, or the like.

As a specific example, the acid amide compound may be 3-methoxy-N,N-dimethylpropanamide, 3-ethoxy-N,N-dimethylpropanamide, 3-propoxy-N,N-dimethylpropanamide, 3-butoxy-N,N-dimethylpropanamide, 3-pentoxy-N,N-dimethylpropanamide, 3-hexyloxy-N,N-dimethylpropanamide, 3-methoxy-N,N-diethylpropanamide, 3-ethoxy-N,N-diethylpropanamide, 3-propoxy-N,N-diethylpropanamide, 3-butoxy-N, N-diethylpropanamide, 3-pentoxy-N,N-diethylpropanamide, 3-hexyloxy-N,N-diethylpropanamide, 3-methoxy-N,N-dipropylpropanamide, 3-ethoxy-N,N-dipropylpropanamide, 3-propoxy-N,N-dipropylpropanamide, 3-butoxy-N, N-dipropylpropanamide, 3-pentoxy-N,N-dipropylpropanamide, 3-hexyloxy-N,N-dipropylpropanamide, 3-methoxy-N,N-dibutylpropanamide, 3-ethoxy-N,N-dibutylpropanamide, 3-propoxy-N,N-dibutylpropanamide, 3-butoxy-N,N-dibutylpropanamide, 3-pentoxy-N,N-dibutylpropanamide, 3-hexyloxy-N,N-dibutylpropanamide, 3-methoxy-N,N-dipentylpropanamide, 3-ethoxy-N,N-dipentylpropanamide, 3-propoxy-N,N-dipentylpropanamide, 3-butoxy-N,N-dipentylpropanamide, 3-pentoxy-N,N-dipentylpropanamide, 3-hexyloxy-N,N-dipentylpropanamide, 4-methoxy-N,N-dimethylbutanamide, 4-ethoxy-N,N-dimethylbutanamide, 4-propoxy-N,N-dimethylbutanamide, 4-butoxy-N,N-dimethylbutanamide, 4-pentoxy-N,N-dimethylbutanamide, 4-hexyloxy-N,N-dimethylbutanamide, 4-methoxy-N,N-diethylbutanamide, 4-ethoxy-N,N-diethylbutanamide, 4-propoxy-N,N-diethylbutanamide, 4-butoxy-N,N-diethylbutanamide, 4-pentoxy-N,N-diethylbutanamide, 4-hexyloxy-N,N-diethylbutanamide, 4-methoxy-N,N-dipropylbutanamide, 4-ethoxy-N,N-dipropylbutanamide, 4-propoxy-N,N-dipropylbutanamide, 4-butoxy-N,N-dipropylbutanamide, 4-pentoxy-N,N-dipropylbutanamide, 4-hexyloxy-N,N-dipropylbutanamide, 4-methoxy-N,N-dibutylbutanamide, 4-ethoxy-N,N-dibutylbutanamide, 4-propoxy-N,N-dibutylbutanamide, 4-butoxy-N,N-dibutylbutanamide, 4-pentoxy-N,N-dibutylbutanamide, 4-hexyloxy-N,N-dibutylbutanamide, 4-methoxy-N,N-dipentylbutanamide, 4-ethoxy-N,N-dipentylbutanamide, 4-propoxy-N,N-dipentylbutanamide, 4-butoxy-N,N-dipentylbutanamide, 4-pentoxy-N,N-dipentylbutanamide, or 4-hexyloxy-N,N-dipentylbutanamide.

The cleaning agent composition may contain (2) the acid amide compound represented by Chemical Formula 1 in an amount of 10 to 99.8 mass %, preferably 30 to 99 mass %, in the entire cleaning agent composition.

### ((3) Non-Polar Solvent)

The non-polar solvent is an organic solvent having no polarity or having substantially low polarity. The non-polar solvent may be selected from those commonly known as non-polar solvents. The non-polar solvent may not contain heteroatoms. The non-polar solvent may be an unsubstituted alkane, alkene, or aryl. As an example, the non-polar solvent may be a saturated aliphatic hydrocarbon, an unsaturated aliphatic hydrocarbon, a saturated alicyclic hydrocarbon, an unsaturated alicyclic hydrocarbon, a terpene compound, and/or an aromatic hydrocarbon.

As an example, the saturated aliphatic hydrocarbon may be n-pentane, isopentane, n-hexane, isohexane, n-heptane, isoheptane, n-octane, isooctane, n-nonane, isononane, n-decane, isodecane, undecane, dodecane, tridecane, or the like.

As an example, the unsaturated aliphatic hydrocarbon may be 1-octene, 1-nonene, 1-decene, 1-dodecene, β-myrcene, or the like.

As an example, the saturated alicyclic hydrocarbon may be cyclopentane, cyclohexane, methylcyclohexane, dimethylcyclohexane, ethylcyclohexane, decahydronaphthalene, or the like.

As an example, the unsaturated alicyclic hydrocarbon may be cyclohexene or the like.

As an example, the terpene compound may be p-menthane, o-menthane, m-menthane, diphenylmethane, 1,4-terpin, 1,8-terpin, bornane, norbornane, pinane, thujane, carane, longifolene, geraniol, nerol, linalool, citral, citronellol, menthol, isomenthol, neomenthol, α-terpineol, β-terpineol, γ-terpineol, terpinen-1-ol, terpinen-4-ol, dihydroterpinyl acetate, 1,4-cineole, 1,8-cineole, borneol, carvone, ionone, thujone, camphor, d-limonene, I-limonene, dipentene, or the like.

As an example, the aromatic hydrocarbon may be benzene, toluene, xylene, ethylbenzene, diethylbenzene, trimethylbenzene, triethylbenzene, tetrahydronaphthalene, or the like.

The cleaning agent composition may contain (3) the non-polar solvent in an amount of 0 to 90 mass %, preferably 10 to 50 mass %, in the entire cleaning agent composition. The cleaning agent composition may contain (2) the acid amide compound and (3) the non-polar solvent in a total amount of 75.0 to 99.8 mass % in the entire cleaning agent composition.

### ((4) Ether Component)

The ether component may be an alkyl ether, a glycol ether, or an aryl ether. As the ether component, a single component or a mixture of a plurality of components may be used.

The alkyl ether may be an ether composed of an alkyl group. For example, the alkyl ether may be diethyl ether, di-n-propyl ether, di-n-butyl ether, di-n-pentyl ether, di-n-hexyl ether, or tert-butyl methyl ether.

The glycol ether may be an ether having a hydroxyl group. For example, the glycol ether may be an aryl ether compound such as anisole or diphenyl ether, bis(2-methoxyethyl) ether, bis(2-ethoxyethyl) ether, bis(2-butoxyethyl) ether, or pentaethylene glycol monododecyl ether.

The aryl ether may be an ether having an aryl group. For example, the aryl ether may be ethyl benzyl ether, cresyl methyl ether, diphenyl ether, dibenzyl ether, phenitol, butyl phenyl ether, or diphenyl ether.

The ether can adjust the polarity of the cleaning agent composition. By containing an ether in the cleaning agent composition, a degree of polarity is imparted to the cleaning agent composition, so as to prevent phase separation of the quaternary ammonium salt (particularly, first ammonium salt) and the non-polar solvent in the cleaning agent composition, and to help the quaternary ammonium salt (particularly, first ammonium salt) to permeate into the temporary adhesive material.

The cleaning agent composition may contain (4) the ether component in an amount of 0.1 to 5.0 mass %, preferably 1.0 to 4.0 mass %, in the entire cleaning agent composition.

### (Other Components)

The cleaning agent composition may contain components other than the above (1) to (4). For example, the cleaning agent composition may include water as needed. Here, the water content of the cleaning agent composition is preferably less than 4.0 mass %. The cleaning agent composition may further contain various additives such as a surfactant, a chelating agent, an antioxidant, a rust inhibitor, a defoamer, or a pH adjuster as needed.

A method of preparing the cleaning agent composition is not particularly limited. The cleaning agent composition may be produced by mixing the above components. A mixing order is not particularly limited. The cleaning agent composition may have a flash point of 21° C. or higher. When the flash point is within the above range, the cleaning target object 10 can be safely cleaned.

### (Overview of Method of Manufacturing Semiconductor Mounting Substrate)

Here, a method of manufacturing a semiconductor mounting substrate using the cleaning agent composition of the present embodiment will be described.

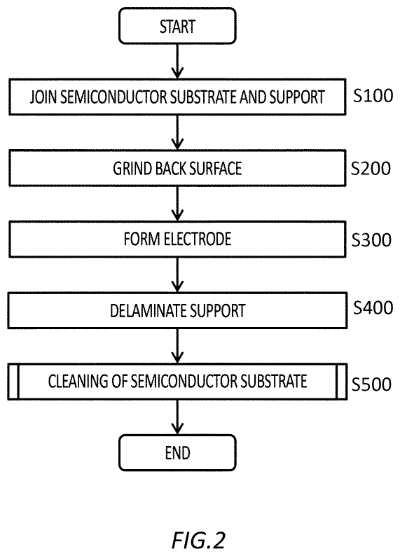

FIG. 2 shows a flow of a method of manufacturing the semiconductor mounting substrate using the cleaning agent composition of the present embodiment. For example, the semiconductor mounting substrate is manufactured by executing each treatment of S100 to S500. A part of S100 to S500 may be omitted. In addition to S100 to S500, other treatments may be executed as needed.

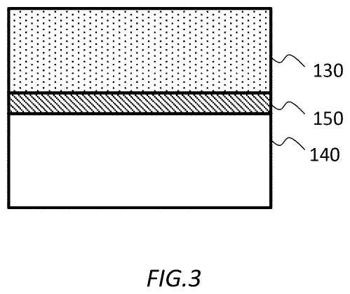

First, in S100, a joining step is executed in which a circuit surface of a semiconductor substrate having a circuit formed on one surface thereof and a support are joined with a silicone-containing temporary adhesive material. FIG. 3 shows a pre-thinning semiconductor substrate 140 joined to a support 130 with a silicone-containing temporary adhesive material 150.

The pre-thinning semiconductor substrate 140 is a semiconductor substrate having a circuit formed on one surface thereof. For example, the pre-thinning semiconductor substrate 140 may be a semiconductor wafer having a semiconductor circuit formed on one surface thereof. The semiconductor wafer may be selected from a silicon wafer, a germanium wafer, a gallium-arsenic wafer, a gallium-phosphorus wafer, and a gallium-arsenic-aluminum wafer.

The temporary adhesive material 150 is an adhesive material containing cured silicone. The temporary adhesive material 150 before curing (hereinafter, also referred to as “uncured composition”) may include a thermosetting organopolysiloxane and/or a thermoplastic organopolysiloxane.

The temporary adhesive material 150 preferably contains siloxane units represented by R¹R²R³SiO_{1/2} (M units) in an amount of 0.001 mol % or more and 60.000 mol % or less, siloxane units represented by R⁴R⁵SiO_{2/2} (D units) in an amount of 10.000 mol % or more and 99.999 mol % or less, siloxane units represented by R⁶SiO_{3/2} (T units) in an amount of 0.000 mol % or more and 0.005 mol % or less, and siloxane units represented by SiO_{4/2} (Q units) in an amount of 0.000 mol % or more and 60.000 mol % or less. In addition, it is more preferable to contain the M units in an amount of 0.001 mol % or more and 35.000 mol % or less, the D units in an amount of 30.000 mol % or more and 99.999 mol % or less, the T units in an amount of 0.000 mol % or more and 0.001 mol % or less, and the Q units in an amount of 0.000 mol % or more and 50.000 mol % or less.

Here, R¹, R², R³, R⁴, R⁵, and R⁶ are organic substituents, and are unsubstituted or substituted monovalent hydrocarbon groups. In this hydrocarbon group, the number of carbon atoms is preferably 1 to 10. Specific examples of the hydrocarbon group include an alkyl group such as a methyl group, an ethyl group, a n-propyl group, an isopropyl group, a n-butyl group, a t-butyl group, a n-pentyl group, a cyclopentyl group, or a n-hexyl group, a cycloalkyl group such as a cyclohexyl group, an aryl group such as a phenyl group or a tolyl group, and a group where some or all of hydrogen atoms of these hydrocarbon groups are substituted with halogen atoms. Among them, the methyl group and the phenyl group are preferable.

The uncured composition may contain, for example, (A-1) an organopolysiloxane having two or more alkenyl groups in one molecule, (A-2) an organohydrogen polysiloxane containing hydrogen atoms (Si—H groups) bonded to two or more silicon atoms in one molecule, and (A-3) a platinum-based catalyst. Here, a molar ratio of Si—H groups in the component (A-2) to alkenyl groups in the component (A-1) is 0.3 or more and 10 or less. In addition, the uncured composition may contain (A-4) an organic solvent or (A-5) a reaction control agent.

The component (A-1) is an organopolysiloxane having two or more alkenyl groups in one molecule. The component (A-1) is, for example, a linear or branched diorganopolysiloxane containing two or more alkenyl groups in one molecule, or an organopolysiloxane having a resin structure having siloxane units represented by SiO4/2 unit (Q units). The component (A-1) is preferably an organopolysiloxane containing 0.6 mol % or more and 9 mol % or less (alkenyl group number of moles/Si number of moles) of alkenyl groups in one molecule.

Such an organopolysiloxane is specifically represented by following Formulas 1, 2, and 3. These may be used alone as a single kind or may be used in combination of two or more kinds.

R⁷₍₃₋ₐ₎ZₐSiO—(R⁷ZSiO)ₘ—(R⁷₂SiO)ₙ-SiR⁷₍₃₋ₐ₎Zₐ (1)

R⁷₂(HO)SiO—(R⁷ZSiO)ₚ₊₂—(R⁷₂SiO)_{q}—SiR⁷₂(OH) (2)

(SiO_{4/2})_{b}(R⁷₃SiO_{1/2})_{c}(R⁷₍₃₋ₑ₎ZₑSiO_{1/2})_{d} (3)

In the above formulas, R⁷ is each independently a monovalent hydrocarbon group having no aliphatic unsaturated bond, Z is each independently a monovalent organic group containing an alkenyl group, a is an integer of 0 to 3, and m and n are numbers such that 2a+m results in an alkenyl group content of 0.6 mol % or more and 9 mol % or less in one molecule. p and q are numbers such that p+2 results in an alkenyl group content of 0.6 mol % or more and 9 mol % or less in one molecule. e is each independently an integer of 1 to 3, and b, c, and d are numbers such that (c+d)/b is 0.3 to 3.0, and d/(b+c+d) is 0.01 to 0.6.

In the above formula, R⁷ is preferably a monovalent hydrocarbon group having 1 to 10 carbon atoms. Specific examples of R⁷ include an alkyl group such as a methyl group, an ethyl group, a propyl group, or a butyl group; a cycloalkyl group such as a cyclohexyl group; an aryl group such as a phenyl group or a tolyl group; and the like. Among them, the alkyl group or the phenyl group is preferable.

Z is preferably an organic group having 2 to 10 carbon atoms. Examples of Z include an alkenyl group such as a vinyl group, an allyl group, a hexenyl group, or an octenyl group; a (meth)acryloylalkyl group such as an acryloylpropyl group, an acryloylmethyl group, or a methacryloylpropyl group; a (meth)acryloxyalkyl group such as an acryloxypropyl group, an acryloxymethyl group, a methacryloxypropyl group, or a methacryloxymethyl group; a cyclohexenyl ethyl group, a vinyloxypropyl group, and the like. Among them, the vinyl group is industrially preferable.

In above Formula 1, when a is 1 to 3, a molecular chain end is blocked with an alkenyl group. This highly reactive molecular chain end alkenyl group allows a reaction to be completed in a short time, which is preferable. Further, a=1 is preferable industrially and from the viewpoint of cost. The property of the alkenyl group-containing diorganopolysiloxane is preferably in the form of oil or raw rubber.

Above Formula 3 represents an organopolysiloxane having a resin structure. In above Formula 3, e=1 is preferable industrially and from the viewpoint of cost. In addition, the product of the average value of e and d/(b+c+d) is preferably 0.02 to 1.50, and more preferably 0.03 to 1.0. The organopolysiloxane having a resin structure may be used as a solution dissolved in an organic solvent.

The component (A-2) is a crosslinking agent, and is an organohydrogen polysiloxane having at least two, preferably three or more hydrogen atoms (Si—H groups) bonded to silicon atoms in one molecule. The organohydrogen polysiloxane is linear, branched, or cyclic. For example, the organohydrogen polysiloxane has at least two, more preferably two or more and 100 or less, and still more preferably three or more and 50 or less hydrogen atoms (Si—H groups) bonded to silicon atoms in one molecule, and can be used in a linear, branched, or cyclic form.

The viscosity of the component (A-2) at 25° C. is preferably 1 mPa·s or more and 5,000 mPa·s or less, and more preferably 5 mPa·s or more and 500 mPa·s or less. The organohydrogen polysiloxane may be used alone as a single kind or may be used in combination of two or more kinds.

It is desirable that the component (A-2) is blended in an amount such that the molar ratio of Si—H groups in the component (A-2) to alkenyl groups in the component (A-1) (Si—H groups/alkenyl groups) is preferably 0.3 or more and 10 or less, and more preferably 1.0 or more and 8.0 or less. When the molar ratio is 0.3 or more, a crosslinking density does not become excessively low, and an uncured composition layer can also be suitably cured. When the molar ratio is 10 or less, the crosslinking density does not become excessively high, and sufficient adhesive strength and tack can be obtained. In addition, when the molar ratio is 10 or less, the usable time of the uncured composition can be lengthened.

The component (A-3) is a platinum-based catalyst (that is, a platinum group metal catalyst). Examples of the platinum-based catalyst include chloroplatinic acid, an alcohol solution of chloroplatinic acid, a reaction product of chloroplatinic acid and an alcohol, a reaction product of chloroplatinic acid and an olefin compound, a reaction product of chloroplatinic acid and a vinyl group-containing siloxane, and the like. The platinum-based catalyst may be used alone as a single kind or may be used in combination of two or more kinds. It is desirable that the component (A-3) is blended in an amount, based on the total of the component (A-1) and the component (A-2), such that a platinum group metal content (mass equivalent) is preferably 1 ppm or more and 5,000 ppm or less, and more preferably 5 ppm or more and 2,000 ppm or less. When the amount is 1 ppm or more, the curability of the uncured composition layer is hardly deteriorated. Therefore, it is possible to suppress a decrease in crosslinking density and a decrease in holding power. When the amount is 5,000 ppm or less, the usable time of the uncured composition can be lengthened.

The component (A-4) is an organic solvent. The organic solvent is not particularly limited as long as it can dissolve the components of the uncured composition. Examples of the organic solvent include a hydrocarbon-based solvent such as pentane, hexane, cyclohexane, isooctane, nonane, decane, p-menthane, pinene, isododecane, or limonene, a silicone-based solvent, and the like. The organic solvent may be used alone as a single kind or may be used in combination of two or more kinds.

When the component (A-4) is used, it is desirable that the component (A-4) is blended in an amount of preferably 10 parts by mass or more and 900 parts by mass or less, more preferably 25 parts by mass or more and 400 parts by mass or less, and still more preferably 40 parts by mass or more and 300 parts by mass or less, based on total 100 parts by mass of the component (A-1) and the component (A-2).

The component (A-5) is a reaction control agent. According to the reaction control agent, when formulating the uncured composition or applying the uncured composition to a substrate, it is possible to suppress thickening or gelation of the uncured composition before heat curing.

Examples of the reaction control agent include 3-methyl-1-butyne-3-ol, 3-methyl-1-pentyne-3-ol, 3,5-dimethyl-1-hexyne-3-ol, 1-ethynylcyclohexanol, 3-methyl-3-trimethylsiloxy-1-butyne, 3-methyl-3-trimethylsiloxy-1-pentyne, 3,5-dimethyl-3-trimethylsiloxy-1-hexyne, 1-ethynyl-1-trimethylsiloxycyclohexane, bis(2,2-dimethyl-3-butynoxy)dimethylsilane, 1,3,5,7-tetramethyl-1,3,5,7-tetravinylcyclotetrasiloxane, 1,1,3,3-tetramethyl-1,3-divinyldisiloxane, and the like. Among them, 1-ethynylcyclohexanol and 3-methyl-1-butyne-3-ol are preferable. The reaction control agent may be used alone as a single kind or may be used in combination of two or more kinds.

When the component (A-5) is used, it is desirable that the component (A-5) is blended in an amount of preferably 0.01 parts by mass or more and 8.0 parts by mass or less, and more preferably 0.05 parts by mass or more and 2.0 parts by mass or less, based on total 100 parts by mass of the component (A-1) and the component (A-2). When the amount is 8.0 parts by mass or less, the curability of the uncured composition layer is hardly deteriorated. When the amount is 0.01 parts by mass or more, the effect of reaction control is sufficiently exhibited.

In addition, the uncured composition may further contain other components. Examples of other components include a filler such as silica; non-reactive polyorganosiloxanes such as polydimethylsiloxane or polydimethyldiphenylsiloxane; an antioxidant such as phenol-based, quinone-based, amine-based, phosphorus-based, phosphite-based, sulfur-based, or thioether-based antioxidants; a light stabilizer such as triazole-based and benzophenone-based light stabilizers; a flame retardant such as phosphoric acid ester-based, halogen-based, phosphorus-based, and antimony-based flame retardants; an antistatic agent such as a cationic activator, an anionic activator, or a nonionic activator; and the like. Each of the other components may be used alone as a single kind or may be used in combination of two or more kinds. The other components are blended within a range that does not hinder the object of the present invention. For example, in order to enhance heat resistance, in a case where a filler is used, the filler is preferably blended in an amount of 50 parts by mass or less, based on total 100 parts by mass of the component (A-1) and the component (A-2).

It is sufficient that the support 130 is a plate that is resistant to high temperature or the like and has sufficient strength. For example, the support 130 may be a silicon wafer, a glass plate, or a quartz wafer. A separation layer may be formed on the surface of the support 130 in advance so that the temporary adhesive material is easily separated.

Joining may be performed by applying an uncured composition on the support 130, drying the uncured composition, attaching the pre-thinning semiconductor substrate 140 to the uncured composition, and then thermally curing the uncured composition. The application of the uncured composition may be executed by spin coating, slit coating, or spray coating. The drying may be performed at a temperature of 80° C. or more and 250° C. or less, preferably 100° C. or more and 230° C. or less, depending on the volatilization conditions of the solvent contained in the uncured composition. Instead of applying and drying the uncured composition, a pre-cured or semi-cured film of the uncured composition may be sandwiched between the support 130 and the pre-thinning semiconductor substrate 140.

The attaching may be performed under reduced pressure and/or applied pressure, and may be further performed under heating (for example, 40 to 250° C.) as needed. The attaching may be performed by a commercially available wafer joining apparatus (for example, EVG520IS and 850 TB (product name) manufactured by EVG, XBC300 (product name) manufactured by SUSS, and SynapseV (product name) manufactured by Tokyo Electron Ltd.).

The thermal curing may be performed under a condition that the uncured composition is sufficiently cured. For example, the thermal curing may be performed at 120° C. or more and 250° C. or less, preferably 140° C. or more and 200° C. or less, for 10 minutes or more and 4 hours or less, and preferably 30 minutes or more and 2 hours or less.

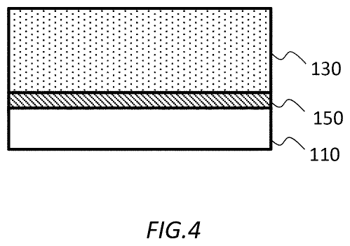

Next, in S200, a thinning step of thinning a surface opposite to the circuit surface (a surface on the support 130 side) of the pre-thinning semiconductor substrate 140 is executed. After the thinning step, the pre-thinning semiconductor substrate 140 becomes the semiconductor substrate 110 thinned as illustrated in FIG. 4.

The thinning may be executed by cutting and/or polishing. The thinning may be executed so that the thickness of the semiconductor substrate 110 is, for example, 5 μm or more and 300 μm or less, preferably 10 μm or more and 100 μm or less. The method of cutting and/or polishing is not particularly limited, and the cutting and/or polishing can be performed by a known method. For example, the polishing may be performed while cooling a substrate and a grindstone (diamond or the like) by applying water. For example, the back surface of the substrate may be subjected to CMP polishing. In addition, for example, the cutting may be performed by using a known grinding processing apparatus (for example, DAG-810 (product name) manufactured by DISCO Corporation).

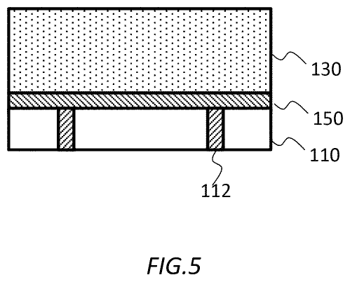

Next, in S300, an electrode formation step of forming an electrode on the surface of the semiconductor substrate 110 opposite to the circuit surface is executed. As illustrated in FIG. 5, the electrode 112 penetrating the semiconductor substrate 110 is formed.

For example, a through electrode (TSV) may be provided as the electrode 112. As the electrode 112, a surface electrode may be formed on a surface (a surface opposite to the temporary adhesive material 150) of the semiconductor substrate 110.

In S300, various types of processing may be performed on the surface (the surface opposite to the temporary adhesive material 150) of the semiconductor substrate 110. For example, in addition to electrode formation, metal circuit formation, protective film formation, dicing, and/or the like may be performed. In these types of processing, necessary processes such as metal sputtering, wet/dry etching, photolithography, and/or a surface oxidation treatment of a semiconductor such as silicon may be executed.

Next, in S400, a delamination step of delaminating the semiconductor substrate 110 and the support 130 from each other is executed. By executing the delamination step, the support 130 is separated from the semiconductor substrate 110.

The delamination step may be executed in a low-temperature environment from room temperature to about 60° C. The delamination step may be executed by a lifting method, a peel method, or a solvent delamination method. The lifting method may be performed by horizontally fixing one of the semiconductor substrate 110 or the support 130 and lifting the other at a constant angle from the horizontal direction.

The peel method may be executed by adhering a dicing tape to the surface of the semiconductor substrate 110 (the surface opposite to the temporary adhesive material 150), vacuum-suctioning the dicing tape surface to a suction surface, and delaminating the support 130 from the semiconductor substrate 110 in a peel-off manner.

In the solvent delamination method, the semiconductor substrate 110 and the support 130 may be delaminated from each other while the temporary adhesive material 150 is at least partially dissolved with a solvent. It is sufficient that the solvent is a material that can dissolve the temporary adhesive material 150, and for example, a hydrocarbon-based, aromatic-based, or ether-based organic solvent with a carbon number of 4 to 20 or the like may be used, and the cleaning agent composition of the present embodiment may be used.

Even after the support 130 is delaminated by the delamination, at least a part of the temporary adhesive material 150 remains as the temporary adhesive material 120 on the surface of the semiconductor substrate 110. This state is the same as that illustrated in FIG. 1, and becomes the cleaning target object 10 in the subsequent cleaning step.

Next, in S500, a cleaning step is executed in which the semiconductor substrate 110 after the delamination is cleaned by using the cleaning agent composition. That is, the semiconductor substrate 110 is cleaned by applying the cleaning agent composition to the semiconductor substrate 110 in which the silicone-containing temporary adhesive material remains on at least one surface. Hereinafter, a cleaning method executed in the cleaning step will be described in more detail.

### (Overview of Method of Cleaning Semiconductor Substrate)

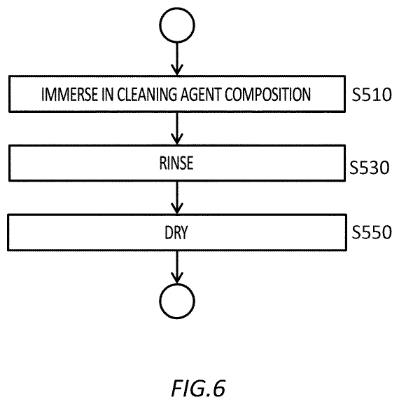

FIG. 6 shows an example of a subflow of the cleaning step (S500). A method of cleaning the semiconductor substrate 110 (S500) may be performed by executing some or all of S510 to S550.

First, in S510, the semiconductor substrate 110 is immersed in the cleaning agent composition. The immersion may be performed for 10 seconds to 30 minutes, preferably 30 seconds to 10 minutes. Ultrasonic cleaning may be performed in combination by adding ultrasonic waves during the immersion. Alternatively/in addition to the immersion, the cleaning agent composition may be sprayed onto the semiconductor substrate 110 and/or the semiconductor substrate 110 may be cleaned with a paddle using the cleaning agent composition. A temperature for the cleaning may be 10 to 50° C., preferably 20 to 40° C.

In S530, rinsing of the cleaned semiconductor substrate 110 is executed. For example, the semiconductor substrate 110 is cleaned with a rinse solution to remove the cleaning agent composition. The rinse solution may be water or alcohol, and may be, for example, isopropanol.

In S550, the rinsed semiconductor substrate 110 is dried. It is sufficient that the drying may be performed under a condition that the rinse solution is sufficiently dried, and for example, the drying may be performed at 30 to 100° C. for 1 to 10 minutes.

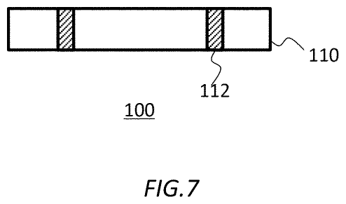

By executing the steps of S100 to S500 in this manner, it is possible to manufacture the semiconductor mounting substrate 100 in which the temporary adhesive material 120 is sufficiently removed from the surface of the semiconductor substrate 110 as illustrated in FIG. 7. In particular, according to the present embodiment, when the polarity of the cleaning agent composition is maintained within an appropriate range, the permeability into the silicone-containing temporary adhesive material can be enhanced, and the silicone-containing temporary adhesive material can be strongly cleaned and removed by utilizing the detergency of the quaternary ammonium salt (particularly, first ammonium salt). As a result, it is possible to obtain the semiconductor mounting substrate 100 in which the temporary adhesive material 120 does not remain or the adhesive material hardly remains.

### EXAMPLES

Hereinafter, examples will be described, but the present embodiment is not limited to the examples.

### Preparation Example 1

Following raw materials were mixed to obtain the cleaning agent composition 1.
(1-1) Tetrabutylammonium fluoride (TBAF) trihydrate 4.7 mass %
(1-2) Quaternary ammonium salt represented by following Chemical Formula A: 0.3 mass %
(2) 3-butoxy-N,N-dimethylpropanamide: 95 mass %

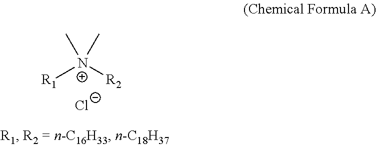

The mixing was performed by the following method. First, the quaternary ammonium salt of (1-1) was added to (2) the acid amide compound, and the mixture was dissolved with sufficient stirring. Next, the quaternary ammonium salt of (1-2) was added, and the mixture was dissolved with sufficient stirring.

### Preparation Example 2

Following raw materials were mixed to obtain the cleaning agent composition 2. The mixing was performed in a procedure similar to that of the cleaning agent composition 1.
(1-1) Tetrabutylammonium fluoride (TBAF) trihydrate: 4.5 mass %
(1-2) Quaternary ammonium salt represented by following Chemical Formula A: 0.5 mass %
(2) 3-methoxy-N,N-dimethylpropanamide: 95 mass %

### Preparation Example 3

Following raw materials were mixed to obtain the cleaning agent composition 3. The mixing was performed in a procedure similar to that of the cleaning agent composition 1.
(1-1) Tetrabutylammonium fluoride (TBAF) trihydrate 4.7 mass %
(1-2) Quaternary ammonium salt represented by following Chemical Formula A: 0.3 mass %
(2) 3-methoxy-N,N-dimethylpropanamide: 95 mass %

### Preparation Example 4

Following raw materials were mixed to obtain the cleaning agent composition 4.

The mixing was performed in a procedure similar to that of the cleaning agent composition 1, then the non-polar solvent of (3) was added, and the mixture was dissolved with sufficient stirring.
(1-1) Tetrabutylammonium fluoride (TBAF) trihydrate 4.7 mass %
(1-2) Quaternary ammonium salt represented by following Chemical Formula A: 0.3 mass %
(2) 3-butoxy-N,N-dimethylpropanamide: 47.5 mass %
(3) p-menthane: 47.5 mass %

### Preparation Example 5

Following raw materials were mixed to obtain the cleaning agent composition 5. The mixing was performed in a procedure similar to that of the cleaning agent composition 4.
(1-1) Tetrabutylammonium fluoride (TBAF) trihydrate 4.7 mass %
(1-2) Quaternary ammonium salt represented by following Chemical Formula A: 0.3 mass %
(2) 3-butoxy-N,N-dimethylpropanamide: 47.5 mass %
(3) Ethylcyclohexane: 47.5 mass %

### Preparation Example 6

Following raw materials were mixed to obtain the cleaning agent composition 6.
(1-1) Tetrabutylammonium fluoride (TBAF) trihydrate 4.7 mass %
(2) 3-butoxy-N,N-dimethylpropanamide: 95 mass %
(4) Pentaethylene glycol monododecyl ether: 0.3 mass %

The mixing was performed by the following method. First, the quaternary ammonium salt of (1-1) was added to (2) the acid amide compound, and the mixture was dissolved with sufficient stirring. Next, the ether component of (4) was added, and the mixture was dissolved with sufficient stirring.

### Preparation Example 7

Following raw materials were mixed to obtain the cleaning agent composition 7.
(1-1) Tetrabutylammonium fluoride (TBAF) trihydrate 4.7 mass %
(1-2) Quaternary ammonium salt represented by following Chemical Formula A: 0.3 mass %
(9) N,N-dimethyloctanamide: 95 mass %

The mixing was performed by the following method. First, the quaternary ammonium salt of (1-1) was added to (9) N,N-dimethyloctanamide, and the mixture was dissolved with sufficient stirring. Next, the quaternary ammonium salt of (1-2) was added, and the mixture was dissolved with sufficient stirring.

### Example 1

An uncured composition was prepared as follows. A solution of 100 parts by mass of polydimethylsiloxane, which has 2.0 mol % of vinyl groups at both ends and side chains, has molecular ends blocked with SiMe2Vi groups, and has a number average molecular weight (Mn) of 50,000 as measured by GPC, and 400 parts by mass of isododecane was added and mixed with 3.5 parts (2 mol with respect to an alkenyl group) of an organohydrogen polysiloxane represented by following Formula M-1 and 0.7 parts of ethynylcyclohexanol. Further, 0.5 parts of a platinum catalyst CAT-PL-5 (manufactured by Shin-Etsu Chemical Co., Ltd.) were added, and the mixture was filtered through a 0.2 μm membrane filter to obtain an uncured composition.

A 200 mm glass wafer (thickness: 700 μm) as a support was prepared. The uncured composition was spin-coated on the support, and then heated on a hot plate at 100° C. for 5 minutes to form a layer of a temporary adhesive material (thickness: 35 μm). Next, a silicon wafer (thickness: 725 μm) having a diameter of 200 mm was joined as a semiconductor substrate to the support. The joining was performed by a wafer joining apparatus (EVG520IS (product name) manufactured by EVG). In addition, the joining was performed at a joining temperature of 50° C., an inner pressure of a chamber at the time of joining of 10-3 mbar or less, and a load of 10 kN. After the joining, the joined semiconductor substrate was heated at 200° C. for 2 hours using an oven to cure the temporary adhesive material, and cooled to room temperature.

Next, the back surface (a surface opposite to the support side) of the semiconductor substrate was ground. Specifically, the back surface of the silicon wafer was ground using a diamond grindstone with a grinder (DAG810 (product name) manufactured by DISCO Corporation). The grinding was performed to a final substrate thickness of 50 μm.

Next, a simulated heating step was performed as a treatment equivalent to processing on the back surface of the semiconductor substrate. Specifically, the semiconductor substrate subjected to the back surface grinding was heated on a hot plate at 260° C. for 10 minutes.

The support was delaminated from the semiconductor substrate. Specifically, a dicing tape was attached to the back surface (circuit non-formed surface) of the silicon wafer by using a dicing frame, and this dicing tape surface was set on a suction plate by vacuum suction. Thereafter, the glass wafer and the temporary adhesive material were delaminated from each other at room temperature by lifting one point of the glass wafer with tweezers.

Next, the surface (a surface on the delamination side) of the semiconductor substrate was cleaned with the cleaning agent composition 1. Specifically, the silicon wafer was immersed in the cleaning agent composition 1 at room temperature for 5 minutes, then rinsed with isopropanol, and air-dried.

### Example 2

The same steps similar to those in Example 1 were performed by using the cleaning agent composition 2 instead of the cleaning agent composition 1.

### Example 3

The same steps similar to those in Example 1 were performed by using the cleaning agent composition 3 instead of the cleaning agent composition 1.

### Example 4

The same steps similar to those in Example 1 were performed by using the cleaning agent composition 4 instead of the cleaning agent composition 1.

### Example 5

The same steps similar to those in Example 1 were performed by using the cleaning agent composition 5 instead of the cleaning agent composition 1.

### Example 6

The same steps similar to those in Example 1 were performed by using the cleaning agent composition 6 instead of the cleaning agent composition 1.

### Comparative Example

The same steps similar to those in Example 1 were performed by using the cleaning agent composition 7 instead of the cleaning agent composition 1.

### (Analysis Evaluation)

The cleaning in the examples was analyzed and evaluated. The cleaned semiconductor substrate of each example was analyzed by X-ray photoelectron spectroscopy (XPS) to analyze element distribution on the surface. As a measuring apparatus, PHIQuanteraSXM manufactured by ULVAC-PHI, Inc. was used. The analysis was performed using a monochromatized Alkα as an X-ray source at an output of 25 W (15 kV, 100 μm diameter), a photoelectron extraction angle of 45°, a pass energy of 55.0 eV, and a step resolution of 0.05 eV.

The Si content in each example is shown in the following table. The Si content in the table excludes Si derived from the silicon substrate.

| EXAMPLE | EXAMPLE | EXAMPLE | EXAMPLE | EXAMPLE | EXAMPLE | COMPARATIVE |
|---|---|---|---|---|---|---|
| 1 | 2 | 3 | 4 | 5 | 6 | EXAMPLE |
| 2% | 2% | 2% | 3% | 1% | 2% | 24% |

As shown in Table 1, in Examples 1 to 6 satisfying the requirements of the present invention, satisfactory cleanability was obtained in a short time with respect to the silicone-containing temporary adhesive remaining on the substrate. Therefore, the subsequent semiconductor processing process can be performed satisfactorily. On the other hand, in the comparative example in which the acid amide compound did not have a heteroatom, a large amount of Si remained, and it was shown that the cleanability was unsatisfactory. The substrate cleaned in the comparative example could not be used in the subsequent semiconductor processing process.

While the present invention has been described by way of the embodiments, the technical scope of the present invention is not limited to the above-described embodiments. It is apparent to persons skilled in the art that various alterations or improvements can be made to the above-described embodiments. In addition, the matters described with regard to the particular embodiment can be applied to other embodiments with a range without causing technical contradictions. In addition, each constitutional element may have features similar to those of other constitutional elements which have the same name and have the different numerals. It is also apparent from description of the claims that the embodiments to which such modifications or improvements are made may be included in the technical scope of the present invention.

It should be noted that each process of the operations, procedures, steps, stages, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

### EXPLANATION OF REFERENCES

10: cleaning target object;
100: semiconductor mounting substrate;
110: semiconductor substrate;
112: electrode;
120: temporary adhesive material;
130: support;
140: pre-thinning semiconductor substrate; and
150: temporary adhesive material.

1. A cleaning agent composition for semiconductor cleaning comprising:
a quaternary ammonium salt; and
an acid amide compound represented by following Chemical Formula 1: 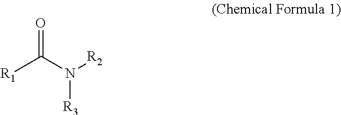
wherein R₁ to R₃ are organic groups, and R₁ contains at least one heteroatom, and
Chemical Formula 1 does not include a cyclic structure in which two or more selected from R₁ to R₃ are linked.

2. The cleaning agent composition for semiconductor cleaning according to claim 1, wherein
R₁ has a carbon number of 4 or more.

3. The cleaning agent composition for semiconductor cleaning according to claim 1, wherein
R₁ includes a —R—O—R′ structure, and R and R′ are alkyl groups.

4. The cleaning agent composition for semiconductor cleaning according to claim 1, wherein
at least one of R₂ or R₃ has a carbon number of 5 or more.

5. The cleaning agent composition for semiconductor cleaning according to claim 1, wherein
R₂ and R₃ are alkyl groups.

6. The cleaning agent composition for semiconductor cleaning according to claim 1, wherein
the quaternary ammonium salt is a first ammonium salt which is represented by R_{A}R_{B}R_{C}R_{D}N⁺F⁻ and in which R_{A} to R_{D} are each independently selected from an alkyl group, an aryl group, and an aralkyl group.

7. The cleaning agent composition for semiconductor cleaning according to claim 6, wherein
the first ammonium salt is contained in an amount of 0.1 to 20.0 mass % in an entire cleaning agent composition.

8. The cleaning agent composition for semiconductor cleaning according to claim 1, wherein
the quaternary ammonium salt contains
a first ammonium salt which is represented by R_{A}R_{B}R_{C}R_{D}N⁺F⁻ and in which R_{A} to R_{D} are each independently selected from an alkyl group, an aryl group, and an aralkyl group, and
a second ammonium salt which is represented by R_{E}R_{F}R_{G}R_{H}N⁺X⁻ and in which R_{E} to R_{H} are each independently selected from an alkyl group, an aryl group, and an aralkyl group, and X is selected from Cl, Br, I and OH.

9. The cleaning agent composition for semiconductor cleaning according to claim 8, wherein
the first ammonium salt is contained in an amount of 0.1 to 20.0 mass % in an entire cleaning agent composition.

10. The cleaning agent composition for semiconductor cleaning according to claim 8, wherein
the second ammonium salt is contained in an amount of 0.1 to 5.0 mass % in an entire cleaning agent composition.

11. The cleaning agent composition for semiconductor cleaning according to claim 1, further comprising
a non-polar solvent.

12. The cleaning agent composition for semiconductor cleaning according to claim 11, wherein
the non-polar solvent does not contain heteroatoms.

13. The cleaning agent composition for semiconductor cleaning according to claim 11, wherein
the acid amide compound and the non-polar solvent are contained in a total amount of 75.0 to 99.8 mass % in an entire cleaning agent composition.

14. The cleaning agent composition for semiconductor cleaning according to claim 8, further comprising
an ether component.

15. The cleaning agent composition for semiconductor cleaning according to claim 14, wherein
the ether component is contained in an amount of 0.1 to 5.0 mass % in an entire cleaning agent composition.

16. The cleaning agent composition for semiconductor cleaning according to claim 1, wherein
a water content is less than 4.0 mass %.

17. The cleaning agent composition for semiconductor cleaning according to claim 1, wherein
the cleaning agent composition is used to clean a silicone-containing temporary adhesive material remaining on a semiconductor substrate.

18. A method of cleaning a semiconductor substrate, comprising
applying the cleaning agent composition according to claim 1 to a semiconductor substrate in which a silicone-containing temporary adhesive material remains on at least one surface to clean the semiconductor substrate.

19. A method of manufacturing a semiconductor mounting substrate, comprising:
joining a circuit surface of a pre-thinning semiconductor substrate having a circuit formed on one surface thereof and a support with a silicone-containing temporary adhesive material;
thinning an opposite surface of the circuit surface of the pre-thinning semiconductor substrate to form a semiconductor substrate;
forming an electrode on the opposite surface of the semiconductor substrate;
delaminating the semiconductor substrate and the support from each other; and
cleaning the semiconductor substrate after the delaminating by using the cleaning agent composition according to claim 1.

20. A method of manufacturing a semiconductor mounting substrate, comprising:
joining a circuit surface of a pre-thinning semiconductor substrate having a circuit formed on one surface thereof and a support with a silicone-containing temporary adhesive material;
thinning an opposite surface of the circuit surface of the pre-thinning semiconductor substrate to form a semiconductor substrate;
forming an electrode on the opposite surface of the semiconductor substrate;
delaminating the semiconductor substrate and the support from each other; and
cleaning the semiconductor substrate after the delaminating by using the cleaning agent composition according to claim 2.
